(19) United States
(12) Patent Application Publication
(10) Pub. No.: US 2003/0068908 A1
(43) Pub. Date: Apr. 10, 2003

(54) Electrical contact for improved wiping action

(76) Inventors: Jeffrey J. Brandt, Maple Grove, MN (US); John E. Nelson, Brooklyn Park, MN (US); Trevor G. Lindblom, North Branch, MN (US)

Correspondence Address: NAWROCKI, ROONEY & SIVERTSON, P.A., Broadway Place East, Suite 401, 3433 Broadway Street N.E., Minneapolis, MN, 55413, US

(21) Appl. No.: 10/231,619

(22) Filed: Aug. 29, 2002

Related U.S. Application Data
(60) Provisional application No. 60/316,533, filed on Aug. 31, 2001.

(51) Int. Cl. H05K 1/00

(52) U.S. Cl. 439/71

(57) ABSTRACT

A contact for use in an IC test socket having a body with a generally linear interface surface. The contact is adapted to be pivotally movable with respect to the socket.

### CROSS-REFERENCE TO RELATED APPLICATIONS

This is a regular application filed under 35 U.S.C. §111(a) claiming priority, under 35 U.S.C. §119(e)(1), of provisional application Ser. No. 60/316,533, previously filed Aug. 31, 2001 under 35 U.S.C. § 111(b).

### TECHNICAL FIELD

The present invention deals broadly with the field of electrical interconnect systems. More specifically, the invention is related to the design of the contacts of an integrated circuit (IC) socket, such as a test socket for testing terminals of an IC package.

### BACKGROUND OF THE INVENTION

Some important mechanical considerations in the design of contacts for an IC socket are the degree and type of wiping action or scrub that is provided within the interconnect system. Such wiping action prevents oxide build-up on the socket contact and/or the device terminal and enables a connection to be established between the socket contacts and corresponding integrated circuit terminals.

It is preferable that the wiping action occur predominantly as a result of movement of a socket contact relative to a location along a corresponding integrated circuit terminal (that is, lead or contact pad). In the prior art, if the wiping action occurs predominantly on the length of the lead/pad in a direction toward the end of the lead/pad, the corresponding socket contact may scrub beyond the end of a lead or pad and thus disengage the connection between the socket contact and the device lead/pad. Similarly, if the wiping action is in the opposite direction, the movement may adjust the connection point between the terminal and the socket contact off of the surface of the terminal and onto, for example, an arm of the terminal extending up to the body of the package. These problems will most likely occur with smaller lead/pad surfaces. Thus, a socket contact that minimizes the actual distance moved along the corresponding terminal will exhibit improved performance with a wider range of leads/pads.

The effectiveness of the wiping action is primarily determined by the design of the socket contact. The orientation of socket contacts of the prior art result in only a small area of wiping along the socket contact relative to the amount of wiping occurring along the corresponding integrated circuit lead/pad. This is primarily due to the lead/pad contacting the outside surface of the socket contact rather than the inside, with the outside and inside being defined with respect to the center of the socket. Another potential cause is the steep angle of the surface of the socket contact.

An IC socket of the prior art generally receives an integrated circuit such that each lead/pad of the integrated circuit engages a portion of the corresponding socket contact extending outwardly from the socket. As the leads/pads engage the socket contacts, a wiping action or scrubbing occurs over the interfacing surfaces as a result of the socket contacts being elastomerically mounted and the elastomer providing a biasing force against the pressing of the socket contact. Some prior art socket contacts have a generally uniformly curved or rounded interface region. These socket contacts provide excellent wiping characteristics. It is at the interface region that the lead engages the socket contact. As the integrated circuit is urged into the socket, the lead/pad displaces the socket contact to create a wiping action over the engaged surfaces of the lead/pad and the socket contact.

A prior art “S” shaped socket contact having a rounded interface surface will typically have approximately 0.0553 mm of scrub distance on the socket contact and 0.2345 mm of scrub distance on the lead at an optimum depressed depth of 0.500 mm. The lead/pad engages the socket contact at the region of the contact that extends outwardly from the socket. As the lead/pad depresses and rotates the socket contact, the portion of the contact engaged by the lead/pad will have apparent inward movement with respect to the end of the lead/pad. This causes a wiping action over a corresponding length of the lead/pad. In contrast, only a small portion of the socket contact is scrubbed. This wiping action also may limit the range of leads/pads that can be used with the socket contact. It would be advantageous to design a socket contact having a shape that allows a greater amount of scrub distance on the contact surface, lesser scrub on the lead/pad, and allows contact engagement for a wider range of lead/pad styles.

### SUMMARY OF THE INVENTION

The present invention provides a contact that has many of the above-referenced considerations. For example, the present invention provides an improved contact having a shape and position that allows for improved scrub and wiping action along an interface surface of the contact, lesser scrub on the corresponding lead/pad of an integrated circuit, and thus allows for use with a wider range of lead/pad lengths.

The present invention includes, in the preferred embodiment, a contact for use in an IC socket having a body with a generally linear interface surface thereon. The interface surface can be adapted to be pivotally movable with respect to the socket. The interface surface may have a slightly convex shape over its length. The interface surface is preferably constructed and arranged to be angled with respect to a predefined angle of contact in its undepressed state and designed such that the angle increases as the surface is depressed by the terminal of an IC package.

The body of the socket contact may be a generally “S” shape. In this embodiment, the “S” shape has a top surface and a bottom surface and the planar interface surface is preferably the top surface.

Additionally, the socket contact body may be biased within the IC socket. The biasing may be provided by any means known in the art, but, preferably, an elastomeric member is utilized to provide a biasing force.

The socket contact can be adapted to be pivotably fixed, at a fixation member formed on the IC socket, in proximity to the bottom surface, which allows the socket contact to pivot around the fixation member. In one embodiment of the design, the interface surface is generally angled inward and rotates inward with respect to the socket when a force is applied by engagement of an IC terminal. The biasing mechanism is connected to the socket contact to pivotally bias the pivotal movement of the contact with respect to the socket.

The present invention is particularly useful in an IC socket having a body with a plurality of slots formed therein. The contact body and the biasing mechanism are then positioned in one of the slots. The biasing mechanism in this embodiment is preferably an elastomeric cross member spanning the slot in which the biasing mechanism is positioned. The pivotal movement of the socket contact is preferably accomplished by connection of the socket contact, at a location on the contact that is proximate the bottom surface, to the socket. This connection may be made to a cross member formed on the socket.

Other structures and advantages of the present invention will be readily appreciated in view of the accompanying drawings and detailed description provided.

### BRIEF DESCRIPTION OF THE DRAWINGS

FIG. 1 is a side view of a prior art “S” shaped contact;

FIG. 2 is a side view of an embodiment of an “S” shaped contact constructed according to the present invention;

FIG. 3 is a side view of a prior art “S” shaped contact illustrating wiping on both a contact interface surface and a lead surface of an IC;

FIG. 4 is a side view of an embodiment of an “S” shaped contact constructed according to the present invention illustrating wiping on both a contact interface surface and a lead surface of an IC;

FIG. 5 is a perspective view of a prior art “S” shaped contact in an IC test socket; and

FIG. 6 is a side view of a prior art “S” shaped contact in an IC test socket.

### DESCRIPTION OF THE PREFERRED EMBODIMENTS

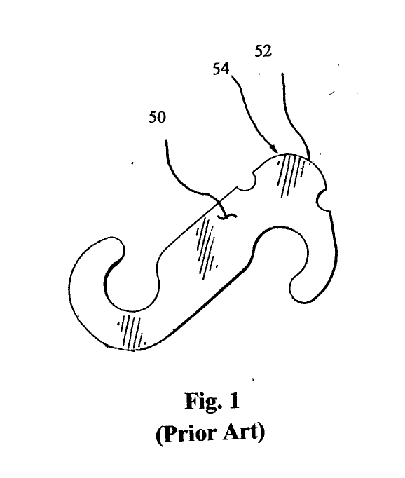

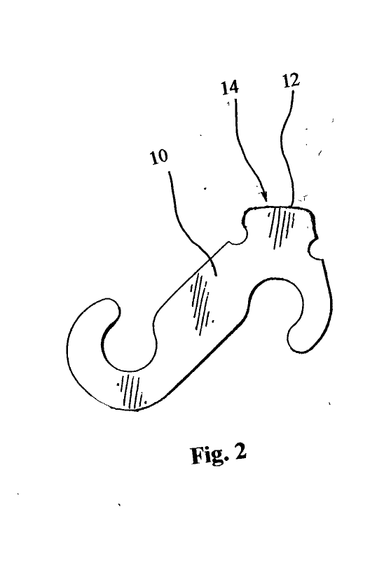

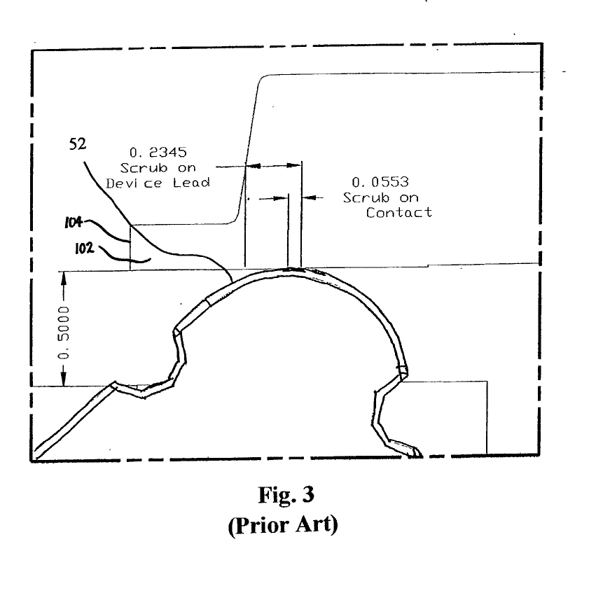

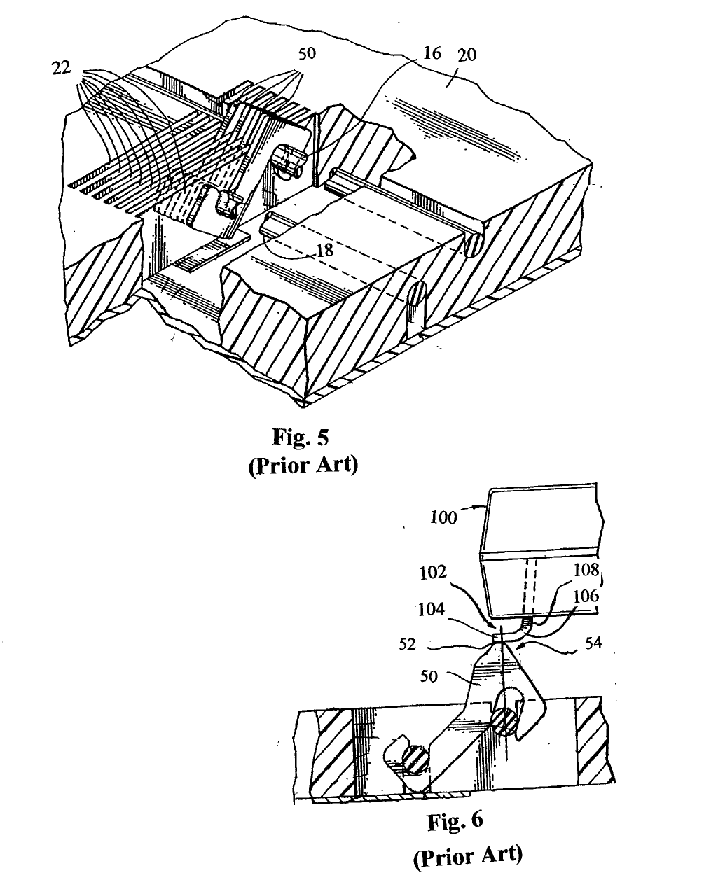

The present invention provides an improved contact having a shape and orientation with respect to an integrated circuit terminal 102 that allows for improved scrub and wiping action along an interface surface of the contact, lesser scrub on the corresponding terminal of the integrated circuit, and thus a wider range of terminal areas. For example, with regard to “S” shaped contacts as shown in FIGS. 1, 3, and 5, and 6, the prior art utilizes a socket contact 50 having an interface surface 52 that is formed by an arcuate edge at the top 54 of the “S”-shaped contact 50. The terminal or lead 102 of an IC package 100, as seen in FIGS. 3 and 6, is shown extending downward in engagement with the top 54 of the socket contact 50.

The lead 102 has a contact end 104, an arm 106, and a second end 108. The contact end 104 is generally parallel to the body of the package 100 with the arm 106 angled upward toward the body of the package 100. The second end 108 extends into the body of the package 100.

The contact 50 is typically positioned and arranged such that, when the contact 50 is urged downward by engagement of lead 102, lead 102 is wiped in a rightward direction as seen in FIG. 6. This causes more wiping action being brought to bear on the lead 102 than may be desired.

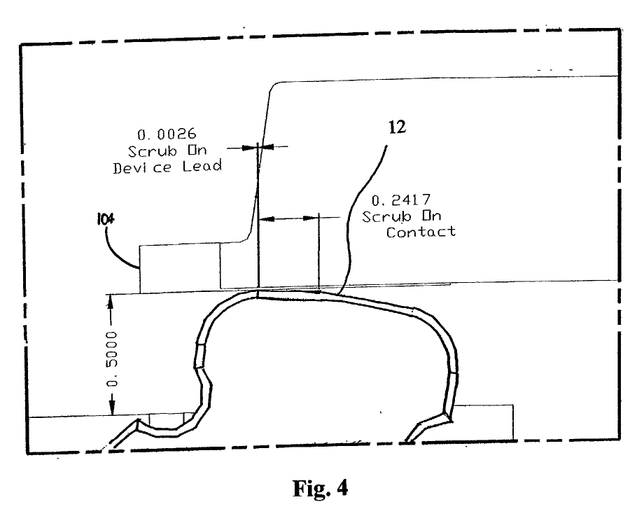

The present invention provides a novel orientation and structure of a socket contact (for example, as in the embodiment shown in FIG. 4). In this embodiment, the wiping action is in a leftward direction as viewed in FIG. 4, thereby allowing for the concentration of the wiping action on the interface surface 12 of the socket contact 10 and less on the lead 102.

The present invention includes a contact 10 for use in an IC socket 20 having a body with a generally linear (or at least having a significant radius of curvature) interface surface 12 thereon. The interface surface 12 is adapted to be pivotally movable with respect to the socket 20. As shown in FIG. 4, the interface surface 12 may have a slightly convex shape over its length. Additionally, the interface surface 12 is preferably constructed and arranged to be angled with respect to a predefined angle of contact in its undepressed state and preferably designed such that the angle increases as the surface 12 is depressed by the terminal 102 of an IC package 100. The predefined angle is the angle at which the terminal approaches the socket contact 10. For example, if the interface surface 12 is oriented horizontally and the approach is perpendicular to the interface surface 12, the angle is 90 degrees. Additionally, in FIG. 6, the direction of movement of the lead 102 is from directly above the socket contact 10, and the interface surface is oriented generally horizontally. In the present invention, if the interface surface is generally horizontal and the movement of the lead 102 is generally perpendicular, as contact 10 is deflected by the lead 102, the interface surface 12 has an angle larger than 90 degrees with respect to the approach angle than it did before the deflection of the socket contact 10.

The body of the socket contact 10 is preferably generally an “S” shape. Any suitable contact shape, however, might be utilized within the scope of the invention. In this embodiment, the “S” shaped socket contact 10 has a top surface 12 and a bottom surface 14. As shown, the generally linear interface surface is preferably at the top surface 12 and, therefore in the embodiment shown, the interface surface is also identified by the reference numeral 12.

Additionally, the socket contact 10 may be biased within socket 20. The biasing may be provided by any means known in the art. For example, an elastomeric member 16 may be utilized to provide a biasing force. The socket contact 10 can be adapted to be pivotably fixed to a fixation member 18 carried by the socket 10 in proximity to bottom surface 14 of the socket contact 10. Such an assembly allows the socket contact 10 to pivot around the fixation member 18.

In one embodiment of the design, the interface surface 12 is angled and rotates inward with respect to the socket 20 when a force is applied by engagement of a lead 102. The biasing elastomeric member 16 is connected to the socket contact 10 to pivotally bias socket contact 10 for pivotal movement with respect to socket 20.

The present invention is particularly useful in an IC socket 20 having a body with a plurality of slots 22 formed therein. The body of the socket contact 10 is positioned in one of the slots 22. The biasing mechanism 16 is preferably an elastomeric cross member spanning slots 22. The pivotal movement of the socket contact 10 is accomplished by pivotal connection of the socket contact 10, proximate the bottom surface 14, to the socket 20. This connection may be made by a cross member such as fixation member 18.

The present invention can be used on an “S” type socket contact such as those disclosed in U.S. Pat. Nos. 5,947,749, and 5,634,801 wherein an upper edge of the socket contact is the portion engaged by a corresponding lead. In this embodiment, each of the two inner reverse curves of the “S” captures a corresponding elastomeric member such that, when the lead engages the top of the corresponding socket contact, a deflection occurs wherein the “S” socket contact rotates in one direction and the elastomeric member biases the movement. This embodiment produces the result illustrated in FIG. 4 wherein the scrub on the device lead was 0.0026 mm and the scrub on the socket contact was 0.2417 mm. This represents a significant reduction of device lead scrubbing and an increase of socket contact scrubbing.

It will be understood that this disclosure, in many respects, is only illustrative. Changes may be made in details, particularly in matters of shape, size, material, and arrangement of parts without exceeding the scope of the invention. Accordingly, the scope of the invention is as defined in the language of the appended claims.

What is claimed is:

1. Apparatus for use in an integrated circuit test socket wherein a surface of a contact is engaged by a terminal of an integrated circuit, comprising:
means mounting the contact for pivoting as it is engaged by the terminal; and
wherein the contact has an interface surface which is slightly convex.

2. Apparatus according to claim 1, wherein said interface surface has a proportionally large radius of curvature.

3. Apparatus according to claim 1, wherein, as the terminal of the integrated circuit engages and pivots the contact, wiping action between the integrated circuit terminal and said interface surface of the contact is minimized along the integrated circuit terminal and maximized along the interface surface of said contact.

4. Apparatus according to claim 1, wherein said contact is generally “S”-shaped.

5. Apparatus according to claim 4, wherein said contact has a top surface and a bottom surface, and wherein said interface surface is defined in said top surface.

6. Apparatus according to claim 1, wherein said contact is elastomerically biased within the IC test socket.

7. Apparatus according to claim 1, wherein said contact has a top and a bottom surface, said top surface defining said interface surface, wherein said contact is pivotably fixed at a fixation member of the test socket proximate said bottom surface such that said contact can pivot around the fixation member.

8. A contact for use in a test socket for interfacing the contact with a lead of an IC package, comprising:
a contact body having an interface surface, said surface for engaging a lead of an IC package such that said interface surface rotates inward with respect to the socket when a force is applied thereto by engagement by a lead of the IC.

9. A contact assembly for use in an IC socket, comprising:
a contact body having a generally linear interface surface and being adapted to be pivotally movable; and
biasing means connected thereto to pivotally bias said contact.

10. A contact assembly according to claim 9, further comprising a test socket having a body with a plurality of slots formed therein, said contact body positioned in one of said slots.

11. A contact assembly according to claim 10, wherein said biasing means comprises an elastomeric cross-member spanning said slot in which said contact is positioned.

12. A contact assembly according to claim 9, wherein said contact has a top and a bottom surface, and wherein pivotal movement is limited by connection of said contact proximate said bottom surface to the socket.

13. Apparatus in an integrated circuit test socket for transmission of a signal between a terminal of an integrated circuit and a second terminal spaced from the integrated circuit terminal, comprising:
a contact having an interface surface engagable by a terminal of an integrated circuit and a second surface in engagement with a second terminal;
means mounting the contact for compliant engagement by a terminal of the integrated circuit;
wherein the compliant engagement of the contact by the terminal of the integrated circuit will effect wiping action therebetween, and wherein the wiping action is maximized on the contact interface surface and minimized on the terminal of the integrated circuit.

14. Apparatus for use in an integrated circuit test socket wherein a surface of a contact is engagable by a terminal of an integrated circuit, comprising:
means mounting the contact for controlled deflection as it is engaged by the terminal of the integrated circuit; and
wherein, as said controlled deflection occurs, wiping action on the contact is maximized and wiping action on the terminal of the integrated circuit is minimized.
